(19) United States
(12) Patent Application Publication
(10) Pub. No.: US 2014/0073138 A1
(43) Pub. Date: Mar. 13, 2014

(54) METHOD FOR PLASMA ETCHING AND PLASMA ETCHING APPARATUS THEREOF

(71) Applicants: Ming-Yu HUANG, Qionglin Township (TW); Min-Chi Hwang, Hsinchu City (TW)

(72) Inventors: Ming-Yu HUANG, Qionglin Township (TW); Min-Chi Hwang, Hsinchu City (TW)

(21) Appl. No.: 13/611,464

(22) Filed: Sep. 12, 2012

(51) Int. Cl. H01L 21/3065

(52) U.S. Cl. 438/716; 156/345.3; 257/E21.218

(57) ABSTRACT

A method for plasma etching is provided, wherein a substrate pre-defining a plurality of to-be-etched segments is secured on a movable stage, and a spray area of plasma from a plasma gun is limited to get a spray-area-limited plasma. Then, at least one of the to-be-etched segments is positioned in an etch position in turn by a step and repeat manner, to make the to-be-etched segments in the etch position to be etched by the spray-area-limited plasma. A plasma etching apparatus is also provided, so that the uniformity of the plasma etching process may be controlled precisely to raise the etching uniformity.

### BACKGROUND OF THE INVENTION

1. Field of the Invention

The present invention relates to a plasma etching technology, and, more especially, to a method and apparatus for step-etching by a plasma gun.

2. Description of the Prior Art

Etching techniques to remove material layers from a silicon substrate are commonly used in semiconductor fabrication processes. Various dry and wet etchants are available, with each etchant offering specific etching characteristics, including material selectivity, etch uniformity and edge profile control. Plasma etching is one form of dry etching that employs a gas and plasma energy to create a chemical reaction that etches the desired material layer.

A conventional plasma etching system includes a chamber, vacuum system, a gas supply and a power source. After loading a silicon wafer onto a pedestal in the chamber, the vacuum system reduces the pressure and a reactive gas is supplied to the chamber. An electrode in the chamber is energized by a power source to energize the gas to a plasma state, producing ions, electrons and radicals. A bias applied to the substrate develops an electric field proximate the substrate to attract ions of the reactive gas to the substrate. These ions and the radicals synergistically etch the substrate according to a pattern in a mask overlying the substrate.

On the other hand, with the development of the wafer having larger diameters, e.g., 12 inches or 18 inches, the non-uniformity of etching is a major concern. However, the uniformity of the present plasma etching process is still problematic due to many other operational parameters of the equipment. This problem is especially serious when manufacturing highly-integrated semiconductor devices.

### SUMMARY OF THE INVENTION

One object of this invention is to provide a method for plasma etching and a plasma etching apparatus thereof, wherein the uniformity of the plasma etching process may be controlled precisely as the smaller plasma reaction area on the substrate, so as to raise the etching uniformity and apply to the wafer having larger diameters, e.g., 12 inches or 18 inches.

Another object of this invention is to provide a method for plasma etching and a plasma etching apparatus thereof, to have the advantages of easy operation and high etching uniformity.

Accordingly, one embodiment of the present invention provides a method for plasma etching including: limiting a spray area of a plasma from a plasma gun to get a spray-area-limited plasma; and positioning at least one of a plurality of to-be-etched segments pre-defined on a substrate in turn in an etch position by a step and repeat manner, to make the to-be-etched segments in the etch position to be etched by the spray-area-limited plasma.

Another embodiment of the present invention provides a plasma etching apparatus including: a processing chamber; a movable stage operable to secure a substrate with a plurality of to-be-etched segments thereon in the processing chamber; a plasma gun arranged on a top of the processing chamber, wherein the plasma gun has an outlet to output plasma into the processing chamber; a limit unit arranged below the outlet to limit a spray area of a plasma from the outlet and get a spray-area-limited plasma to etch at least one of the to-be-etched segments; and wherein at least one of the to-be-etched segments is positioned in an etch position in turn by a step and repeat manner, to make the to-be-etched segments in the etch position to be etched by the spray-area-limited plasma.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram showing a plasma etching apparatus according to an embodiment of the present invention.

FIG. 2 is a schematic diagram showing a substrate with a plurality of pre-defining to-be-etched segments thereon.

FIG. 3 is a schematic diagram showing a positionable blade structure with a rectangular aperture.

### DESCRIPTION OF THE PREFERRED EMBODIMENT

The detail description is provided below and the preferred embodiments described are only for the purpose of description rather than for limiting the present invention.

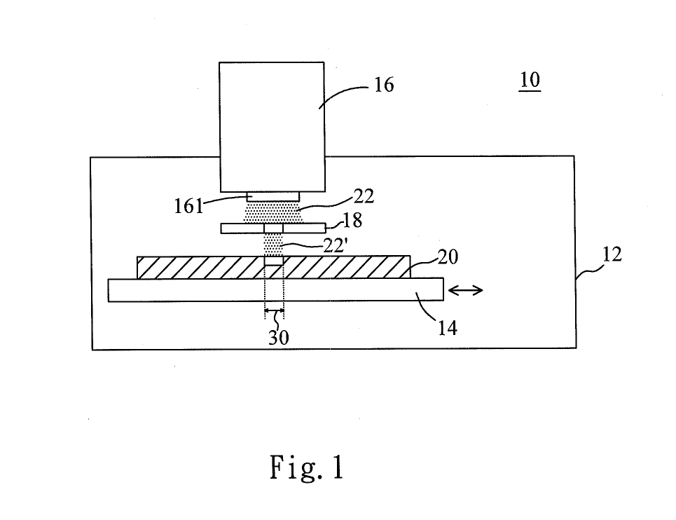

FIG. 1 is a schematic diagram showing a plasma etching apparatus according to an embodiment of the present invention. As shown in FIG. 1, the plasma etching apparatus 10 includes: a processing chamber 12; a movable stage 14; a plasma gun 16 and a limit unit 18. The movable stage 14 is configured in the processing chamber 12 for horizontally securing thereon a target substrate 20, which is a semiconductor wafer, for example. The plasma gun 16 is arranged on the top of the processing chamber 12 and portion of the plasma gun 16 passes through the top surface of the processing chamber 12 to make an outlet 161 of the plasma gun 16 in the processing chamber 12. The plasma gun 16 is directed at a surface of the substrate 20 separated by a distance sufficiently short that a plasma stream 22 exiting the plasma gun 26 from the outlet 161 during plasma gun 16 operation will impinge directly on the substrate 20 surface. The limit unit 18 is arranged below the outlet 161 to confine the plasma stream 22 and limit a spray area of the plasma 22 from the outlet to get a spray-area-limited plasma 22′. In one embodiment, the limit unit 18 is a mechanical unit, but not limited. In other embodiment, the limit unit 18 may be a magnetic unit or an electric unit.

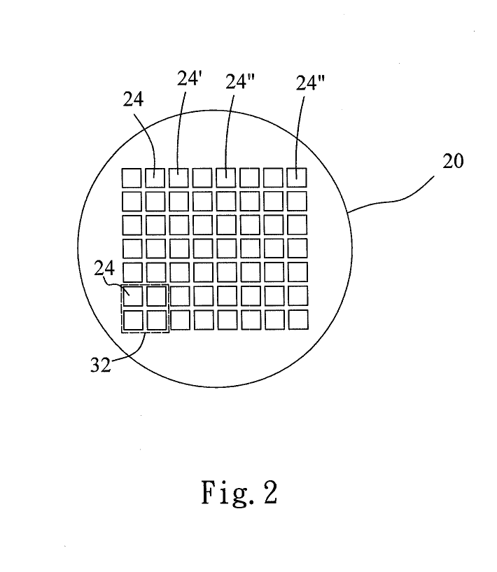

FIG. 2 is a schematic diagram showing a substrate with a plurality of pre-defining to-be-etched segments. As shown in FIG. 1 and FIG. 2, a plurality of the to-be-etched segments 24 are pre-defined on the substrate 20. When proceeding the etching process, the movable stage 14 moves horizontally by a step manner, to position at least one of the to-be-etched segments 24 in turn in an etch position 30, and then the to-be-etched segment 24 in etch position 30 is etched by the spray-area-limited plasma 22′.

In one embodiment, the area of each to-be-etched segment 24 corresponds to a spray area of the spray-area-limited plasma 22′, but not limited. Hence, one to-be-etched segment 24 in etch position 30 is etched by the spray-area-limited plasma 22′ for a period of time. After this to-be-etched segment 24 finished etching, the movable stage 14 moves a single step to make the next to-be-etched segment 24′ be positioned in etch position 30 and then be etched by the spray-area-limited plasma 22′ for a period of time. Continuously, the moving step and the etching step are continued in step and repeat manner until all of the to-be-etched segments 24, 24′ finished etching in turn.

Furthermore, when the movable stage 14 moves a single step, it is not limited to only make the neighboring to-be-etched segment 24′ be positioned in etch position 30, it may cross neighboring segment 24′or few segments and make another pre-decided to-be-etched segment 24″(as shown in FIG. 2, for example) be positioned in etch position 30 and then be etched by the spray-area-limited plasma 22′ for a period of time. Accordingly, the moving step and the etching step are in leaping and repeat manner until all of the to-be-etched segments 24, 24″ finished etching.

In another embodiment, the area of the spray-area-limited plasma 22′ may correspond to a plurality of arrayed to-be-etched segments 24 in etch position 30. The arrayed to-be-etched segments 24, which include four to-be-etched segments 24, for example, are framed by dashed line 32, as shown in FIG. 2. Hence, during every etching step, the spray-area-limited plasma 22′ may etch the four arrayed to-be-etched segments 24 simultaneously for a period of time. Here, the number of the arrayed to-be-etched segments 24 in the etch position 30 corresponds to a spray area of the spray-area-limited plasma 22′.

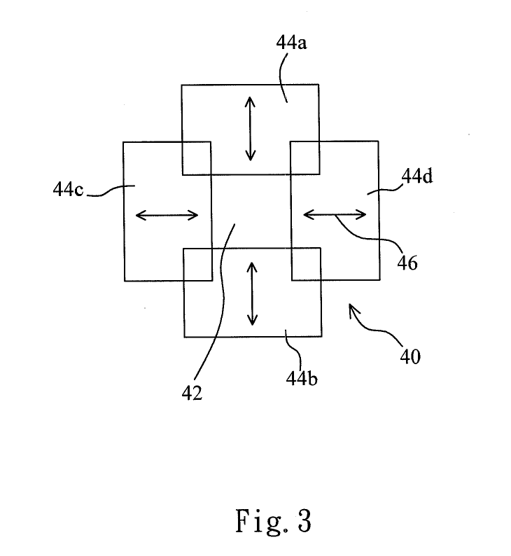

Continuously, the foregoing area of the spray-area-limited plasma 22′ is controlled by the limit unit 18 (shown in FIG. 1), such as a mechanical unit. In one embodiment, the mechanical unit is a positionable blade structure having an aperture, the aperture being of an area that is selectively adjustable in sizes. FIG. 3 is a schematic diagram showing a positionable blade structure 40 with an aperture 42. Here, the area of the aperture 42 is a rectangular shape or a square shape when the aperture 42 is open. As shown in FIG. 3, the variable aperture 42 is formed by two pairs of blade members 44a, 44b, 44c, 44d. To do so, requires separate control of each pair of blade members 44a, 44b, 44c, 44d, horizontal and vertical, as represented by the bilateral arrows 46 in the drawing figure. Here, the rectangular aperture 42 is formed between the straight edges of two pairs of selectively positioned blade members 44a, 44b, 44c, 44d.

In proceeding the etching process, the processing chamber 12 is a vacuum chamber. Generally, to lower the pressure in the processing chamber 12 down to a predetermined pressure, there are disposed an exhaust unit (not shown) to adjust the pressure in the processing chamber 12 to a predetermined pressure. Further, a load-lock chamber (not shown) connecting the processing chamber 12 is used to transport the substrate 20 to be processed from the side of atmosphere to the side of vacuum, an unload-lock chamber (not shown) connecting the processing chamber 12 is used to transport the substrate 20 from the vacuum side to the atmosphere side.

In the present invention, a method for plasma etching including: securing a substrate on a movable stage, wherein the substrate includes a plurality of pre-defining to-be-etched segments regularly arranged thereon; limiting a spray area of a plasma from a plasma gun to get a spray-area-limited plasma; and positioning at least one of the to-be-etched segments in turn in an etch position by a step and repeat manner by the motion of the movable stage, to make the to-be-etched segments in the etch position to be etched by the spray-area-limited plasma.

As the movable stage moves step by step, the pre-defined to-be-etched segments on substrate are etched in turn step by step until the substrate finished the etching process. Hence, the uniformity of the present plasma etching process may be controlled precisely as the smaller plasma reaction area on the substrate, so as to raise the etching uniformity and be able to apply to the wafer having larger diameters, e.g. 18 inches. On the other hand, the movement of the movable stage is a developed technology, so that it is simple to control the movable stage to move step by step, and then achieve the object of etching the substrate in step and repeat manner. This method for plasma etching has the advantages of easy operation and high etching uniformity.

Although the present invention has been explained in relation to its preferred embodiment, it is to be understood that other modifications and variation can be made without departing the spirit and scope of the invention as hereafter claimed.

What is claimed is:

1. A method for plasma etching, comprising:
limiting a spray area of a plasma from a plasma gun to get a spray-area-limited plasma; and
positioning at least one of a plurality of to-be-etched segments pre-defined on a substrate in turn in an etch position by a step and repeat manner, to make the to-be-etched segments in the etch position to be etched by the spray-area-limited plasma.

2. The method for plasma etching according to claim 1, wherein the spray area of the plasma is limited by a mechanical unit, a magnetic unit or an electric unit.

3. The method for plasma etching according to claim 1, wherein the positioning step of the to-be-etched segments is performed by a movable stage securing the substrate thereon.

4. The method for plasma etching according to claim 1, wherein a number of the to-be-etched segments in the etch position corresponds to a spray area of the spray-area-limited plasma.

5. The method for plasma etching according to claim 1, wherein a shape of a spray area of the spray-area-limited plasma is rectangle or square.

6. The method for plasma etching according to claim 1, wherein the movable stage and the substrate is arranged in a vacuum chamber.

7. A plasma etching apparatus, comprising:
a processing chamber;
a movable stage operable to secure a substrate with a plurality of to-be-etched segments thereon in the processing chamber;
a plasma gun arranged on a top of the processing chamber, wherein the plasma gun has an outlet to output plasma into the processing chamber;
a limit unit arranged below the outlet to limit a spray area of a plasma from the outlet and get a spray-area-limited plasma to etch at least one of the to-be-etched segments; and
wherein at least one of the to-be-etched segments is positioned in an etch position in turn by a step and repeat manner, to make the to-be-etched segments in the etch position to be etched by the spray-area-limited plasma.

8. The plasma etching apparatus according to claim 7, wherein the to-be-etched segment is positioned in the etch position by a motion of the movable stage.

9. The plasma etching apparatus according to claim 7, wherein the limit unit is a mechanical unit, a magnetic unit or an electric unit.

10. The plasma etching apparatus according to claim 9, wherein the mechanical unit is a positionable blade structure having an aperture, the aperture being of an area that is selectively adjustable in sizes.

11. The plasma etching apparatus according to claim 10, wherein the area is a rectangular shape or a square shape when the aperture is open.

12. The plasma etching apparatus according to claim 10, wherein a spray area of the spray-area-limited plasma is controlled by the aperture.

13. The plasma etching apparatus according to claim 12, wherein a number of the to-be-etched segments in the etch position corresponds to the spray area of the spray-area-limited plasma.

14. The plasma etching apparatus according to claim 7, wherein the processing chamber is a vacuum chamber.
